(19) United States
(12) Patent Application Publication
(10) Pub. No.: US 2026/0191110 A1
(43) Pub. Date: Jul. 2, 2026

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventors: Sangcheon PARK, Suwon-si (KR); Jinhan PARK, Suwon-si (KR); Miki TAKAKI, Yokohama city (JP); Takashi KARIYA, Yokohama city (JP); Toshiki FURUTANI, Yokohama city (JP)

(73) Assignee: SAMSUNG ELECTRONICS CO., LTD., Suwon-si (KR)

(21) Appl. No.: 19/421,503

(22) Filed: Dec. 16, 2025

(30) Foreign Application Priority Data
Dec. 27, 2024 (JP) 2024-231576
Feb. 12, 2025 (KR) 10-2025-0018276

(51) Int. Cl. H10W 90/24; H10B 80/00; H10W 70/60; H10W 70/685; H10W 72/00; H10W 72/20; H10W 74/10; H10W 90/00

(52) U.S. Cl. CPC H10W 90/24; H10W 70/685; H10W 72/244; H10W 72/823; H10W 90/724; H10B 80/00; H10W 70/611; H10W 74/117

(57) ABSTRACT

Provided is a semiconductor package including a plurality of semiconductor chips having a first surface and a second surface opposite to the first surface, and having an electrode on the second surface, and sequentially stacked in a first direction and offset in a second direction perpendicular to the first direction such that the electrode does not overlap with the first surface, a redistribution wiring layer having a first surface facing the semiconductor chips and electrically connected to the plurality of semiconductor chips, a sealing resin layer sealing the semiconductor chips, and a plurality of through electrodes including pillar-shaped portions, and each of the through electrodes extending in the first direction from the first surface of the redistribution wiring layer toward the electrode of the semiconductor chip through the sealing resin layer.

### CROSS-REFERENCE TO RELATED APPLICATIONS

This application claims priority to Japanese Patent Application No. 2024-231576, filed on Dec. 27, 2024, and Korean Patent Application No. 10-2025-0018276, filed on Feb. 12, 2025 in the Korean Intellectual Property Office (KIPO), the disclosures of which is incorporated herein in their entireties by reference.

### BACKGROUND

### 1. Field

Embodiments of the present disclosure relate to a semiconductor package and a method of manufacturing the semiconductor package.

### 2. Description of Related Art

In products such as Low Power Double Data Rate (LPDDR) memory with a fan-out type semiconductor package, demand for devices with high-capacity, high-performance, and wide input/output (wide I/O) is expected to increase in order to meet market demands. These types of wide I/O devices have been manufactured using a wire post method that utilizes wire bonding technology.

In order to realize wide I/O, miniaturization of wire bonding technology is essential. However, it is very difficult to further miniaturize wide I/Os with a pitch of 60 μm or less due to the technical limitations of the wire post method. In addition, since the wire post method uses gold (Au), the price of which has recently increased significantly, as a bonding material, there is a problem that as usage increases, material costs increases, which reduces the price competitiveness of the product.

A package structure that employs a through dielectric via (TDV) method has been proposed to solve the above problem. The TDV method enables the formation of finer electrodes than related wire bonding techniques by utilizing photolithography, etc. In addition, since the TDV method has a degree of freedom in the selection of usable electrode materials, a reduction in manufacturing costs can be expected.

The semiconductor package may include an electrode formed using the TDV method to connect semiconductor chips that are stacked in a step shape and a redistribution wiring layer. In addition, the electrode formation process may include numerous processes, such as a process of forming a vertical interconnection portion and a horizontal interconnection portion in a dielectric layer, and a process of separately forming a filler bump that connects the redistribution wiring layer and the semiconductor chip through the horizontal interconnection portion.

For this reason, the semiconductor package may have a problem in that the package structure becomes complicated because, in addition to the vertical interconnection portion and the horizontal interconnection portion, the filler bump must be formed between each semiconductor chip and the redistribution wiring layer as an electrode structure. In addition, since the semiconductor package is a package having a complex electrode structure as described above, there is also a problem in that the manufacturing cost inevitably increases due to the large number of manufacturing processes.

### SUMMARY

One or more embodiments provide a fan-out type semiconductor package with high capacity and high performance and having a simplified package structure.

One or more embodiments also provide a method of manufacturing the semiconductor package that is able of reduce manufacturing costs.

One or more embodiments also provide a method of manufacturing the semiconductor package.

According to an aspect of one or more embodiments, there is provided a semiconductor package, including a semiconductor chip stack structure including a plurality of semiconductor chips respectively including a first surface and a second surface opposite to the first surface, and an electrode on the second surface of each semiconductor chip of the plurality of semiconductor chips, wherein the plurality of semiconductor chips are stacked in a first direction and offset in a second direction perpendicular to the first direction such that the electrode on each semiconductor chip of the plurality of semiconductor chips is spaced apart from the first surface of an adjacent semiconductor chip of the plurality of semiconductor chips in the second direction, a redistribution wiring layer including a first surface facing the plurality of semiconductor chips and a second surface opposite to the first surface, and including a connection terminal on the second surface of the redistribution wiring layer that is configured to be electrically connected to a mounting substrate and electrically connected to the plurality of semiconductor chips, a sealing resin layer sealing the plurality of semiconductor chips, and a plurality of through electrodes between the plurality of semiconductor chips and the redistribution wiring layer, each through electrode of the plurality of through electrodes including conductive pillar-shaped portions, wherein each through electrode of the plurality of through electrodes extends in the first direction from the first surface of the redistribution wiring layer through the sealing resin layer toward the electrode of each semiconductor chip of the plurality of semiconductor chips.

According to an aspect of one or more embodiments, there is provided a semiconductor package, including a redistribution wiring layer, a plurality of semiconductor chips sequentially stacked on a first surface of the redistribution wiring layer in a first direction, a first surface of each semiconductor chip of the plurality of semiconductor chips facing the redistribution wiring layer, and the plurality of semiconductor chips being offset in a second direction perpendicular to the first direction to expose an electrode on the first surface of each semiconductor chip of the plurality of semiconductor chips, a sealing resin layer sealing the plurality of semiconductor chips, a connection portion on the electrode of each semiconductor chip of the plurality of semiconductor chips and configured to be electrically connected to the redistribution wiring layer, and a plurality of through electrodes extending from the first surface of the redistribution wiring layer through the sealing resin layer to the connection portion, wherein each through electrode of the plurality of through electrodes includes conductive pillar-shaped portions.

According to still another aspect of one or more embodiments, there is provided a semiconductor package, including a redistribution wiring layer, a plurality of semiconductor chips sequentially stacked on a first surface of the redistribution wiring layer in a first direction, a first surface of each semiconductor chip of the plurality of semiconductor chips facing the redistribution wiring layer, and being offset in a second direction perpendicular to the first direction such that each electrode on the first surface of each semiconductor chip of the plurality of semiconductor chips is exposed, a sealing resin layer sealing the plurality of semiconductor chips, and a plurality of through electrodes extending from the first surface of the redistribution wiring layer through the sealing resin layer toward the electrodes of the plurality of semiconductor chips, wherein each through electrode of the plurality of through electrodes includes conductive pillar-shaped portions, and wherein axis centers of the conductive pillar-shaped portions are offset from each other in the second direction or widths of the conductive pillar-shaped portions are different from each other in the second direction.

### BRIEF DESCRIPTION OF DRAWINGS

Example embodiments will be more clearly understood from the following detailed description taken in conjunction with the accompanying drawings, in which:

FIG. 1 is a cross-sectional view illustrating a semiconductor package mounted on a mounting substrate in accordance to one or more embodiments;

FIG. 2 is a partially enlarged view illustrating a through electrode of FIG. 1;

FIG. 3 is a flow chart illustrating a method of manufacturing a semiconductor package in accordance to one or more embodiments;

FIGS. 4, 5, 6, 7, 8, 9, 10, 11, 12, 13, 14, 15, 16, 17, and 18 are cross-sectional views illustrating a method of manufacturing a semiconductor package in accordance to one or more embodiments;

FIG. 19 is a cross-sectional view illustrating a semiconductor package according to one or more other embodiments;

FIG. 20 is a cross-sectional view illustrating a semiconductor package according to one or more other embodiments;

FIG. 21 is a view illustrating a connection step in a method of manufacturing a semiconductor package according to one or more other embodiments;

FIG. 22 is a cross-sectional view illustrating a semiconductor package according to one or more other embodiments; and

FIG. 23 is a cross-sectional view illustrating a semiconductor package according to one or more other embodiments.

### DETAILED DESCRIPTION

Hereinafter, embodiments will be explained in detail with reference to the accompanying drawings. In the following drawings, same reference numerals refer to the same components, and the size of each component in the drawings may be exaggerated for clarity and convenience of explanation. The embodiments described below are merely examples, and various modifications are possible from such embodiments.

In the following, the terms “upper” and “above” may include not only what is directly above in contact with something, but also what is above without contact. Similarly, the terms “lower” and “below” may include not only what is directly below in contact with something, but also what is below without contact.

As used herein, the singular forms “a,” “an” and “the” are intended to include the plural forms as well, unless the context clearly indicates otherwise. When a part is described as “comprising,” “having,” or “having” a certain element, it does not mean excluding other elements, but may further include other elements, unless otherwise specified to the contrary.

Unless the steps constituting the method are explicitly described in order or described to the contrary, the steps may be performed in any suitable order, and the method is not necessarily limited to the order of the steps described. The use of any examples or exemplary terms is merely for the purpose of illustrating the technical idea, and the scope of the invention is not limited by the examples or exemplary terms, except as otherwise provided by the claims.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

Hereinafter, a semiconductor package 1 in accordance to one or more embodiments will be described.

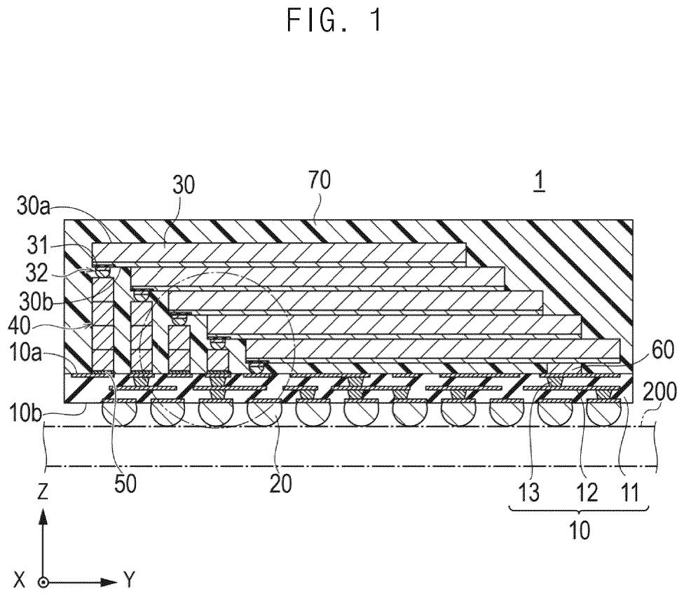

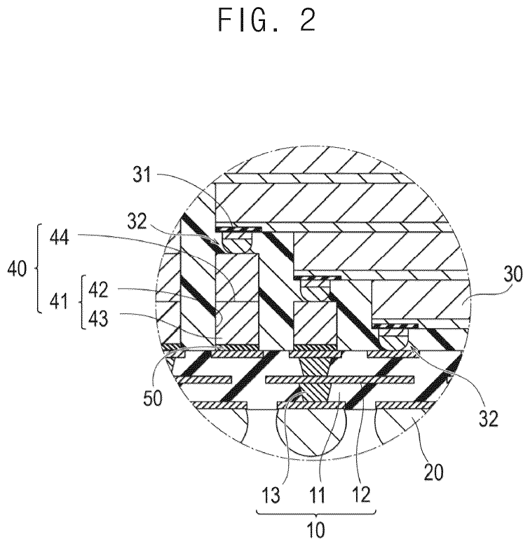

FIG. 1 is a cross-sectional view illustrating a semiconductor package mounted on a mounting substrate in accordance to one or more embodiments. FIG. 2 is a partially enlarged view illustrating a through electrode of FIG. 1.

Here, for convenience of explanation, an XYZ orthogonal coordinate system is set for the semiconductor package 1. A direction parallel to the X-axis within a predetermined plane is referred to as X-axis direction. A direction parallel to the Y-axis orthogonal to the X-axis within a predetermined plane is referred to as Y-axis direction. A direction parallel to the Z-axis orthogonal to each of the X-axis and Y-axis is referred to as Z-axis direction. In one or more embodiments, a direction along the XY plane (X-direction and Y-direction) corresponds to a plane direction orthogonal to a thickness direction (Z-axis direction) of the semiconductor package 1.

The semiconductor package 1 according to one or more embodiments may be a fan-out type semiconductor package. The semiconductor package 1 may be configured as an LPDDR memory. In addition, when the semiconductor package 1 has a fan-out type semiconductor package as its package structure, the type of device may not be particularly limited.

As illustrated in FIGS. 1 and 2, the semiconductor package 1 may include a redistribution wiring layer 10, a connection terminal 20, a semiconductor chip 30, a through electrode 40, a seed layer 50, a support member 60, and a sealing resin layer 70. As illustrated in FIG. 1, the semiconductor package 1 may include a plurality of stacked semiconductor chips 30 and may be mounted on a mounting substrate 200 through the connection terminal 20.

The redistribution wiring layer 10 may include an insulating layer 11, a conductive pattern 12, and a conductive via 13. The redistribution wiring layer 10 may be formed on a carrier substrate 100 made of silicon or glass, as illustrated in the manufacturing method described below. The insulating layer 11 may be formed of an insulating resin, such as, for example, a thermosetting resin such as epoxy resin or a thermoplastic resin such as polyimide. The conductive pattern 12 and the conductive via 13 may be formed of a metal such as, for example, copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof.

The redistribution wiring layer 10 may have an A surface 10a on one side and a B surface 10b on the other side opposite to the A surface 10a. The A surface 10a may be a surface facing the semiconductor chip 30 within the package, and may be a surface on which the seed layer 50 or the support member 60 is formed. The connection terminal 20 for electrically connecting to the mounting substrate 200 may be formed on the B surface 10b. In FIG. 1, the A surface 10a of the redistribution wiring layer 10 may be an upper surface, and the B surface 10b may be a lower surface.

A plurality of the connection terminals 20 may be formed on the B surface 10b of the redistribution wiring layer 10 and may be connected to the conductive pattern 12 of the redistribution wiring layer 10. The connection terminals 20 may be respectively formed as a plurality of solder bumps. The connection terminal 20 may electrically connect the semiconductor package 1 to the mounting substrate 200. The shape of the connection terminal 20 may not be particularly limited as long as it has a shape that can function as a terminal, other than a spherical shape or a hemispherical shape. The material for forming the connection terminal 20 may not be limited to solder, and any material that may electrically connect the semiconductor package 1 and the mounting substrate 200 may be used.

The semiconductor chip 30 may be formed as a semiconductor wafer including a semiconductor element such as silicon or a compound semiconductor such as silicon carbide (SiC). The semiconductor chip 30 may have a first surface 30a on one side and a second surface 30b on the other side on which an electrode 31 or an IC circuit pattern, etc., is formed, opposite to the first surface 30a. As illustrated in FIG. 1, when a plurality of semiconductor chips 30 are stacked, one semiconductor chip 30 may be stacked on the first surface 30a. In FIG. 1, the first surface 30a of the semiconductor chip 30 is an upper surface, and the second surface 30b is a lower surface.

A connection portion 32 for electrically connecting to the through electrode 40 may be provided on the electrode 31. The connection portion 32 may be formed by disposing a micro solder bump on a pillar formed of a metal such as, for example, copper (Cu) or nickel (Ni) or a copper-nickel (Cu—Ni) alloy.

The plurality of stacked semiconductor chips 30 may be stacked such that the electrode 31 and the connection portion 32 provided on the electrode 31 are exposed, as illustrated in FIG. 1. The semiconductor chips 30 may be stacked in a step-like shape by being offset-aligned by a predetermined distance in a same direction (second direction) (Y-axis direction) orthogonal to the first direction (Z-axis direction). For example, the semiconductor chips 30 may be stacked such that the electrode 31 of each chip is offset-aligned in the second direction (Y-axis direction) such that the electrodes of the chips do not overlap each other in the first direction (Z-axis direction). When viewed from the bottom plan view, each of the semiconductor chips 30 may have an overhang portion protruding from one side of the semiconductor chip 30 that is relatively below. The electrode 31 may be provided on a lower surface of the overhang portion of the semiconductor chip 30, i.e., the second surface 30b. The number of stacked semiconductor chips 30 may be at least a plurality (two or more), and the number of stacked semiconductor chips 30 may be arbitrarily set according to the package specifications. In one or more embodiments, the semiconductor package 1 may include five stacked semiconductor chips 30, as illustrated in FIG. 1.

As illustrated in FIG. 1, when the semiconductor chip 30 is located in the lowermost level that is closest to the redistribution wiring layer 10 in the stacked structure, the lowermost semiconductor chip 30 may be directly electrically connected to the conductive pattern 12 of the redistribution wiring layer 10 through the connection portion 32. For example, the connection portion 32 may be directly between the lowermost semiconductor chip 30 and the conductive pattern 12. As illustrated in FIG. 1, when the semiconductor chip 30 is stacked in the lowermost level that is closest to the redistribution wiring layer 10, the lowermost semiconductor chip 30 may be electrically connected to the redistribution wiring layer 10 through the connection portion 32. In the semiconductor package 1, among the semiconductor chips 30, the chip located in the lowermost level is directly connected to the redistribution wiring layer 10 through the connection portion 32, and the other chips may be connected to the redistribution wiring layer 10 through the connection portion 32 and the through electrode 40. For example, the through electrode 40 may be directly between the redistribution wiring layer 10 and the connection portion 32.

The through electrode 40 may electrically connect the redistribution wiring layer 10 and individual semiconductor chips 30. The through electrode 40 may electrically connect the conductive pattern 12 of the redistribution wiring layer 10 and the electrode 31 of the semiconductor chip 30 through the connection portion 32. The through electrode 40 may be formed on the seed layer 50 to form a pair with the semiconductor chip 30 to be connected. The semiconductor chip 30 to be connected to the through electrode 40 may be a plurality of semiconductor chips 30 that are stacked on the semiconductor chip 30 located at the lowermost level.

The through electrode 40 may be formed by stacking one or more pillar-shaped portions 41. The pillar-shaped portion 41 may include a through portion 42 that connects the A surface 10a of the redistribution wiring layer 10 and the connection portion 32 to be connected, and a pillar-shaped electrode including an electrode portion 43 formed by wet plating on the inside of the through portion 42. The pillar-shaped portion 41 may be formed as a cylinder, a cylindrical column, a polygonal cylinder, a polygonal column, etc.

The through electrode 40 may be manufactured, for example, by the following processes. The through electrode 40 may be formed using, for example, a photolithography method and a wet plating method. To form the through electrode 40, a resist layer 110 may be formed to cover the seed layer 50. The resist layer 110 may be patterned form a plurality of through portions 42 penetrating in the thickness direction. A wet plating process may be performed to form the electrode portion 43 in the through portion 42. The pillar-shaped portion 41 included in the through electrode 40 may be completed. In order to match the connection height with the semiconductor chip 30 to be connected, the through electrode 40 may be formed by repeatedly performing the above three processes and stacking the pillar-shaped portions 41 as many times as necessary. By this, the through electrode 40 may be formed to have a height such that the through electrode 40 is connected to the connection portion 32 of the semiconductor chip 30 to be connected.

As illustrated in FIG. 2, when the through electrode 40 is formed by stacking a plurality of pillar-shaped portions 41, a boundary portion 44 may be formed between the pillar-shaped portions 41 adjacent in the stacking direction. Since the boundary portion 44 is formed by repeatedly performing the process of forming the pillar-shaped portion 41, the number of the formed boundary portions 44 may increase as the height of the through electrode 40 increases.

As illustrated in FIG. 1, the through electrode 40 may extend from the A surface 10a of the redistribution wiring layer 10 toward the connection portion 32 of the semiconductor chip 30 to be connected, to penetrate the sealing resin layer 70 along the first direction (Z-axis direction) in the thickness direction of the semiconductor package 1. The through electrode 40 may be directly connected to each connection portion 32 of the semiconductor chip 30 to be connected. Accordingly, since the semiconductor package 1 may directly electrically connect the redistribution wiring layer 10 and the semiconductor chip 30 through the connection portion 32, the package structure may be more simplified.

The seed layer 50 may be provided at the formation location of the through electrode 40 on the A surface 10a of the redistribution wiring layer 10. When removing the resist layer 110, a portion of the seed layer 50 other than the layer formed directly below the through electrode 40 may be removed together. Accordingly, as illustrated in FIG. 1, the seed layer 50 may be disposed between the conductive pattern 12 of the redistribution wiring layer 10 and the through electrode 40, so that the number of seed layers is the same as that of the through electrodes 40. The seed layer 50 may be formed using a surface treatment method such as a plating method. The seed layer 50 may be formed as a conductive metal layer using, for example, copper (Cu), titanium (Ti), a copper (Cu) alloy, or a titanium (Ti) alloy.

The support member 60 may be provided on the A surface 10a of the redistribution wiring layer 10. The support member 60 may be arranged to contact a portion of the second surface 30b of the semiconductor chip 30 that is arranged closest to the redistribution wiring layer 10 among the semiconductor chips 30. Considering the manufacturing method of the semiconductor package 1, the support member 60 may be preferably formed by a plating method using copper (Cu). However, the support member 60 may support the semiconductor chip 30 without damaging a function of the semiconductor package 1. Accordingly, the support member 60 may be formed using another metal such as, for example, nickel (Ni), or a polymer material such as synthetic resin.

The number of the support members 60 may not be particularly limited as long as they may prevent unintended tilting of the semiconductor chip 30 arranged on the redistribution wiring layer 10. In addition, the size of the support member 60 may be appropriately configured according to the package size of the semiconductor package 1, a distance between the redistribution wiring layer 10 and the semiconductor chip 30, an area of the second surface 30b of the semiconductor chip 30, etc. The support member 60 may maintain the mounting posture of the semiconductor chip 30, and/or may electrically connect the semiconductor chip 30 and the redistribution wiring layer 10.

The sealing resin layer 70 may include a sealing resin having insulating properties, such as epoxy resin. The sealing resin included in the sealing resin layer 70 may not be limited thereto, and various other types of resin may be used. The sealing resin layer 70 may be formed by filling a gap with the sealing resin to be provided on and/or cover and surround outer surfaces of the semiconductor chip 30 and the through electrode 40 to become a sealing space. Since the sealing resin layer 70 adjusts the coefficient of linear expansion or elastic modulus, the sealing resin layer 70 may include a non-conductive filler, such as an inorganic filler having a spherical shape or a flat shape, such as silica, as needed. In addition, the sealing resin layer 70 may include, for example, an underfill material that is filled in a fine gap between the redistribution wiring layer 10 and the semiconductor chip 30.

Hereinafter, a method of manufacturing the semiconductor package 1 of FIG. 1 will be described.

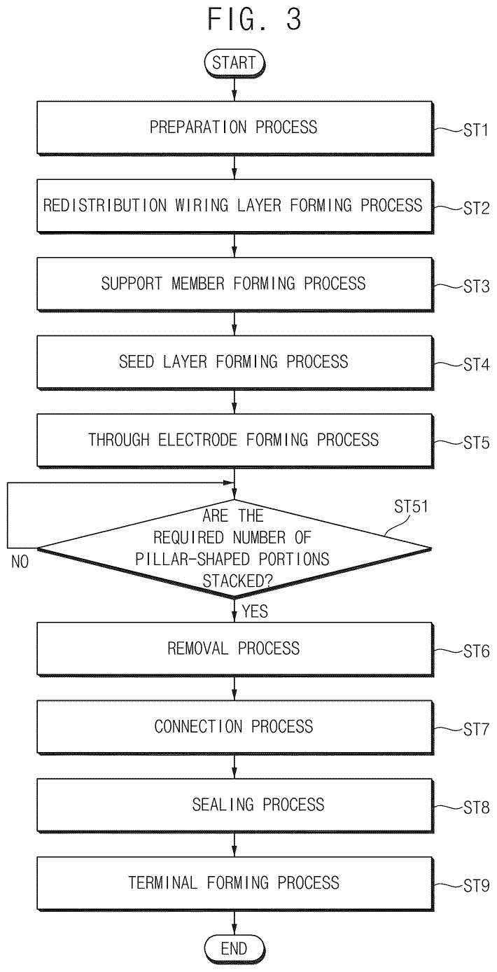

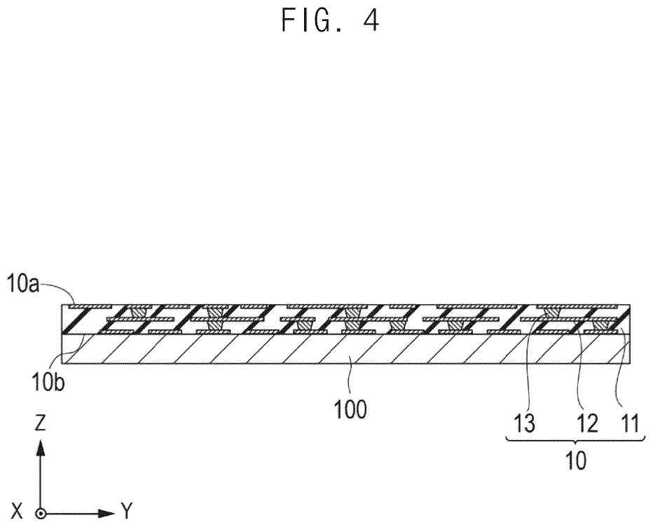

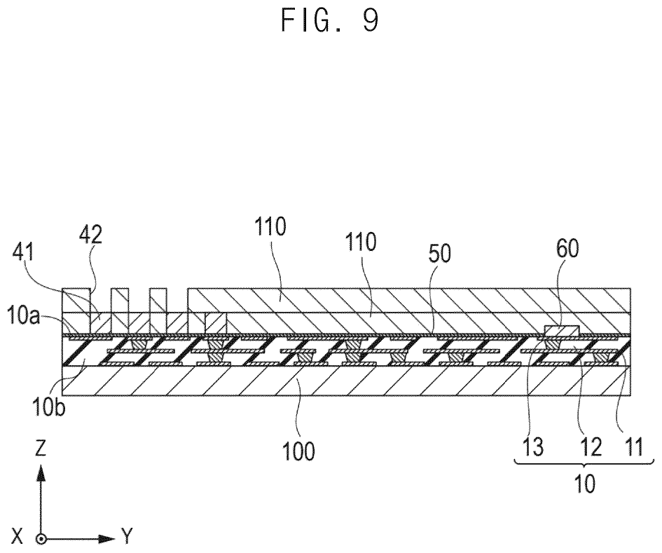

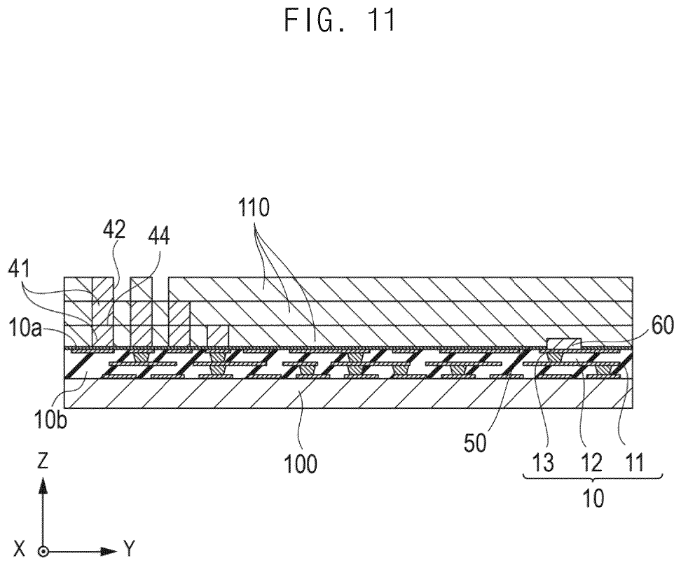

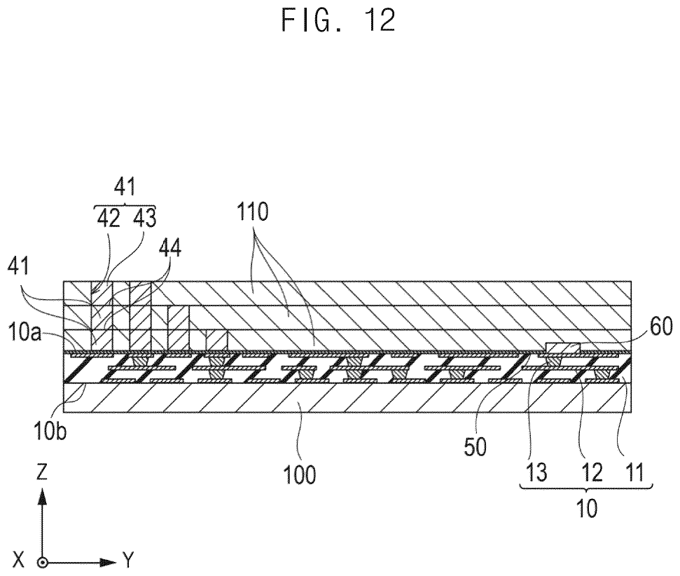

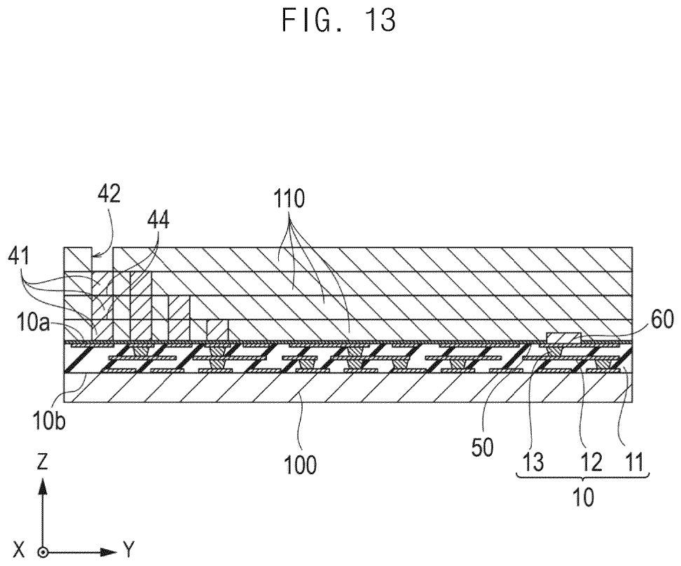

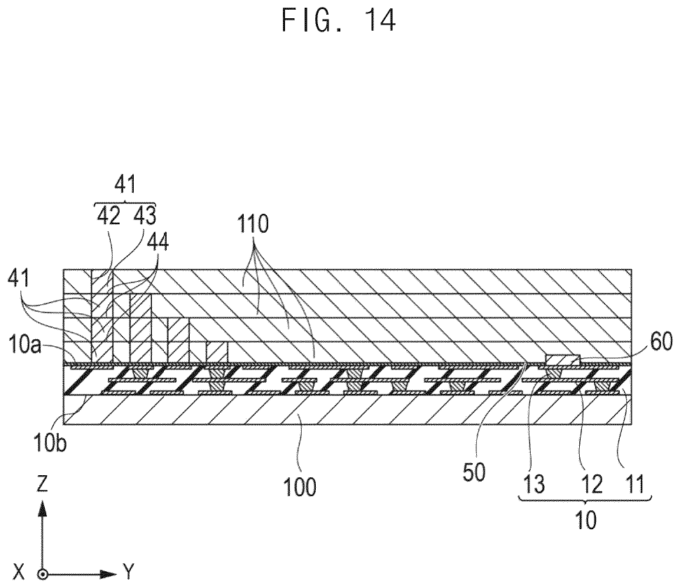

FIG. 3 is a flow chart illustrating a method of manufacturing a semiconductor package in accordance to one or more embodiments. FIGS. 4 to 18 are cross-sectional views illustrating a method of manufacturing a semiconductor package in accordance to one or more embodiments. The manufacturing method illustrated below may appropriately change the order of implementation or include other processes.

The manufacturing method according to one or more embodiments illustrated a structure in which five semiconductor chips 30 are mounted on a redistribution wiring layer 10. However, the number of semiconductor chips 30 mounted (the number of stacked chips) is not limited thereto, and at least two or more semiconductor chips 30 may be stacked.

Referring to FIG. 3, the method of manufacturing the semiconductor package 1 according to example embodiments may include a preparation process (S1), a redistribution wiring layer forming process (S2), a support member forming process (S3), a seed layer forming process (S4), a through electrode forming process (S5), a removal process (S6), a connection process (S7), a sealing process (S8), and a terminal forming process (S9). In addition, the method of manufacturing the semiconductor package 1 may include additional processes other than the processes illustrated in FIG. 3.

In one or more embodiments, in the preparation process (S1), a plurality of semiconductor chips 30 including electrodes 31 and connection portions 32, and a carrier substrate 100 may be formed.

As illustrated in FIG. 4, in the redistribution wiring layer forming process (S2), a redistribution wiring layer 10 may be formed on the carrier substrate 100. The carrier substrate 100 may be a substrate made of, for example, silicon or glass.

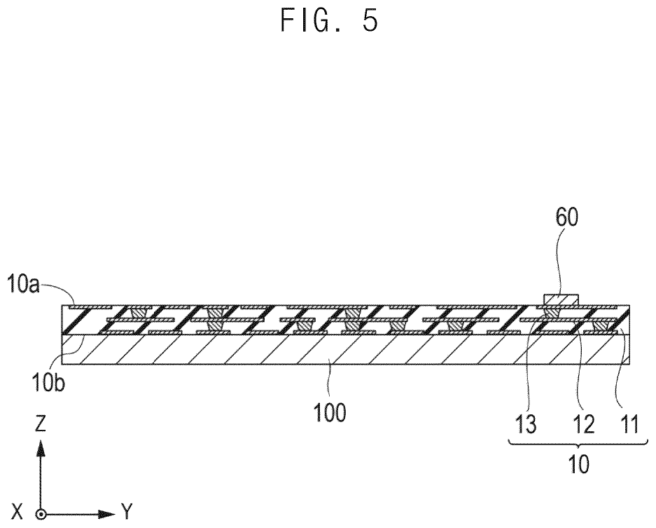

As illustrated in FIG. 5, in the support forming process (S3) a support member 60 for supporting a semiconductor chip 30 may be formed on an A surface 10a of the redistribution wiring layer 10. The support member 60 may be formed using a metal such as, for example, copper (Cu) or nickel (Ni) by a wet plating method. In addition, the support member 60 may be formed using a polymer material such as synthetic resin. As long as the support member 60 may support the semiconductor chip 30 without damaging the function of the semiconductor package 1, the forming method or material of the support member 60 may not be particularly limited.

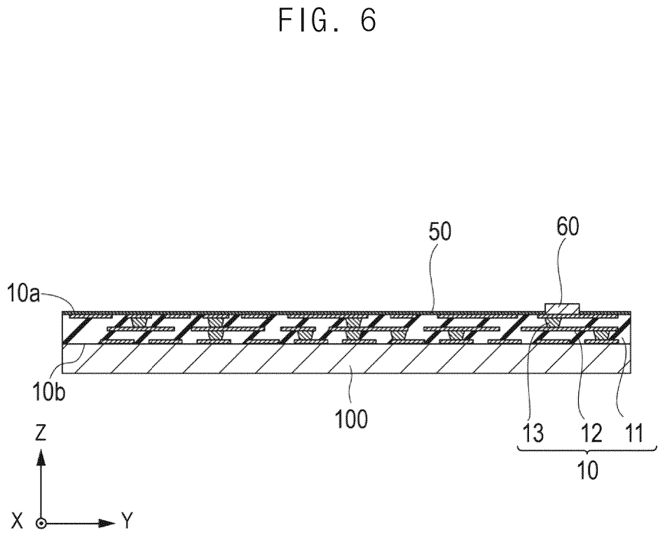

As illustrated in FIG. 6, in the seed layer forming process (S4), a seed layer 50 may be formed on the A surface 10a of the redistribution wiring layer 10. The seed layer 50 may be formed using a metal material such as, for example, copper (Cu), titanium (Ti), etc., on the A surface 10a except for the support member 60 by a plating method, a chemical or physical vapor deposition method.

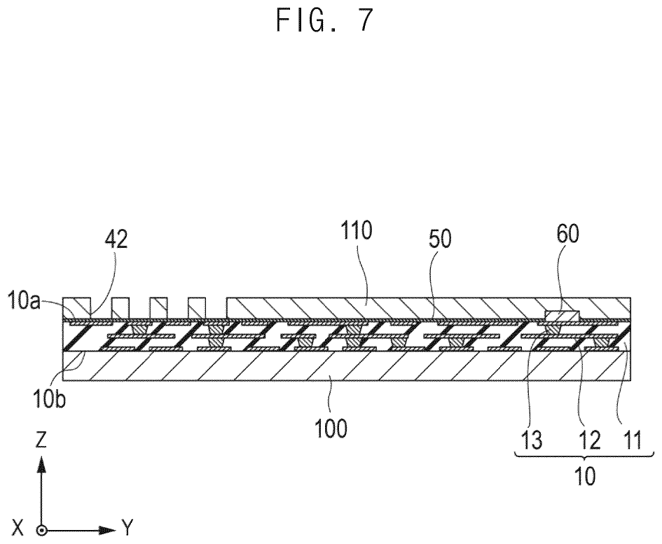

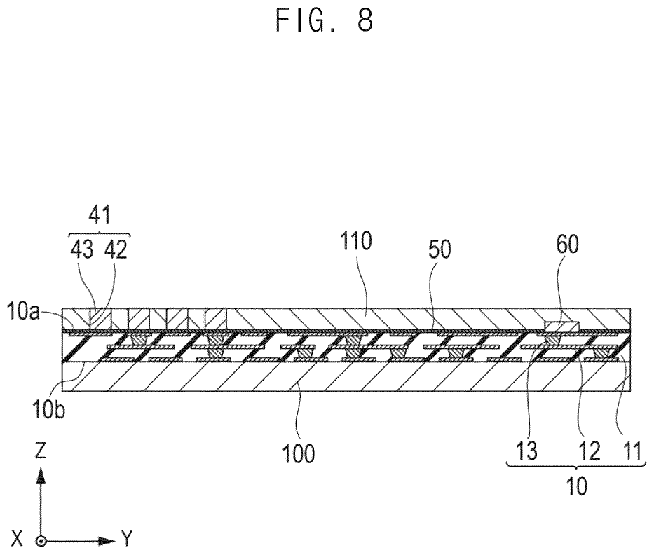

As illustrated in FIG. 7, in the through electrode forming process (S5), a resist layer 110 may be formed by a photolithography method to be provided on and/or cover the seed layer 50, to pattern the resist layer 110 to form a plurality of through portions 42 penetrating the resist layer 110 in a thickness direction (Z direction), and, as illustrated in FIG. 8, to form an electrode portion 43 on each of the penetration portions 42 by a wet plating method.

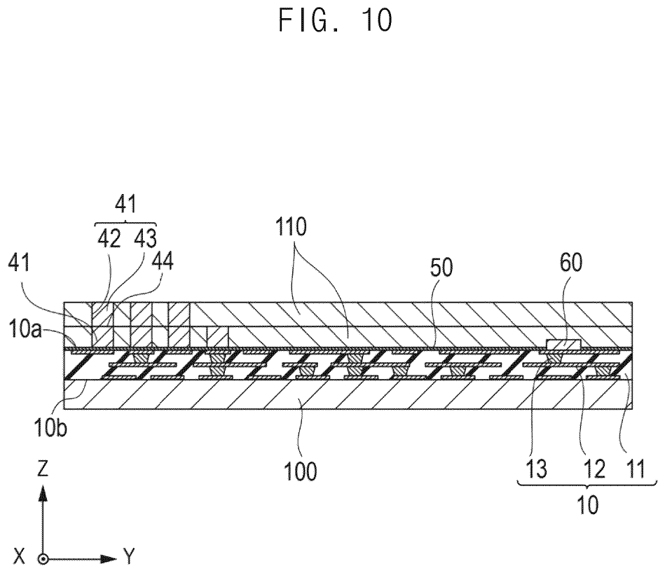

In the through electrode forming process (S5), the through portion 42 may be formed in the resist layer 110 at a position that may be connected to a semiconductor chip 30. The electrode portion 43 may be formed in the through portion 42 using, for example, copper (Cu) by a wet plating method. The through portion 42 and the electrode portion 43 may be a pillar-shaped portion 41 included in the through electrode 40. In addition, when the through electrode 40 is formed by stacking the pillar-shaped portions 41 as illustrated in FIG. 10, a boundary portion 44 may be formed between the pillar-shaped portions 41.

As illustrated in FIGS. 7 to 14, the through electrode forming process (S5) may be repeatedly performed to stepwise stack the pillar-shaped portions 41 included in the through electrode 40 so that the through electrode 40 reaches a connection portion 32 of a semiconductor chip 30 to be connected. For example, in the method of manufacturing the semiconductor package, whether the required number of the pillar-shaped portions 41 that may form the through electrode 40 are stacked (S51) is determined, and when the required number of the pillar-shaped portions 41 is not formed (S51-NO), the process may proceed to the through electrode forming process (S5) to form the pillar-shaped portion 41. When the required number of the pillar-shaped portions 41 are formed in the process S51 (S51-YES), the process may proceed to the next process. In this way, in the through electrode forming process (S5), the pillar-shaped portions 41 may be stacked to form the through electrode 40. Accordingly, a number of boundary portions 44 may be formed between the pillar-shaped portions 41 adjacent to each other in the stacking direction in some of the through electrodes 40 according to the number of stacked pillar-shaped portions 41.

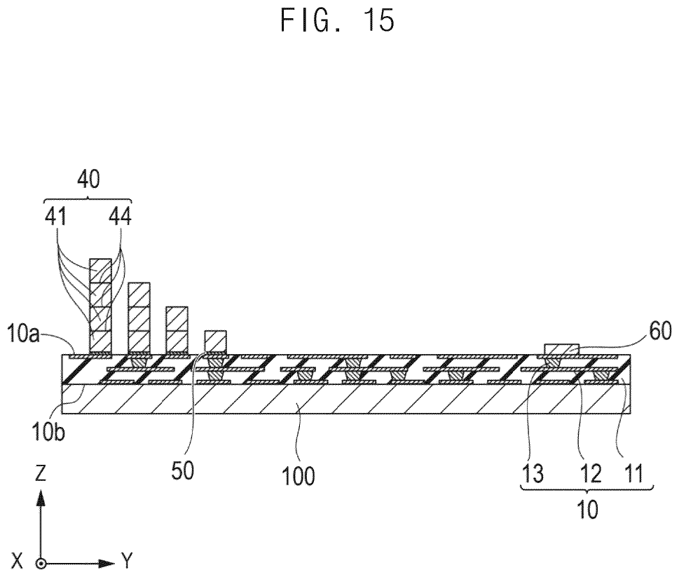

As illustrated in FIG. 15, in a removal process (S6), the resist layer 110 may be removed. In the removal process (S6), an unnecessary portion of the seed layer 50 may be removed together with the resist layer 110. Accordingly, the seed layer 50 may be formed under the through electrode 40.

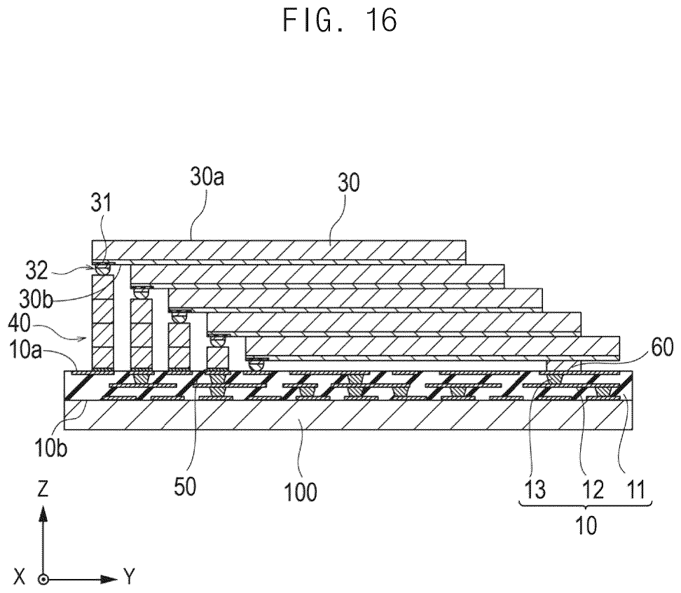

As illustrated in FIG. 16, in the connection process (S7), the semiconductor chips 30 may be sequentially stacked in a first direction along the Z-axis direction, which is the stacking direction, to be offset aligned in a second direction along the Y-axis direction, which is perpendicular to the first direction, so that the connection portions 32 do not overlap, and to connect the through electrode 40 and the connection portion 32.

In the connection process (S7), the semiconductor chips 30 may be stacked to be offset-aligned by a predetermined distance in a same direction (second direction) (Y-axis direction) such that the connection portions 32 are exposed. Accordingly, the stacked semiconductor chips 30 may be stacked in a step-like shape, as illustrated in FIG. 16.

In the connection process (S7), the semiconductor chip 30 located in the lowermost level may be directly connected to the redistribution wiring layer 10, as illustrated in FIG. 16. Each of the semiconductor chips 30 to be stacked may be individually connected to the through electrode 40 through the connection portion 32 formed on an electrode 31, as illustrated in FIG. 16. Since the connection between the redistribution wiring layer 10 and the semiconductor chip 30 to be stacked is made by the connection portion 32 and the through electrode 40, without the need for additional elements, the number of processes of forming unnecessary connection members may be reduced, and the manufacturing cost may be reduced.

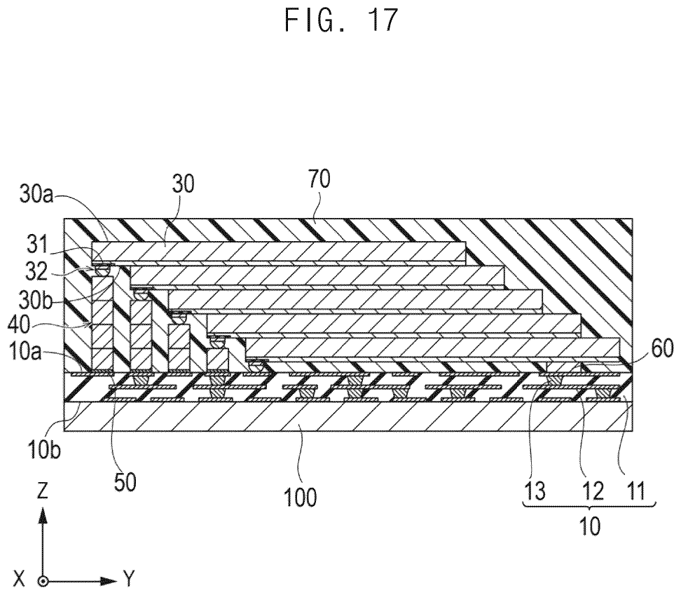

Then, as illustrated in FIG. 17, in the sealing process (S8), a sealing resin layer 70 may be formed to seal the semiconductor chips 30, provided in the connection process (S7). The sealing resin layer 70 may be formed of a resin such as epoxy resin. The sealing resin layer 70 may fill a gap that becomes a sealing space to be provided adjacent to and/or surround the semiconductor chip 30 or the through electrode 40. In addition, in the sealing process (S8), a gap between the redistribution wiring layer 10 and the semiconductor chip 30 may be filled using an underfill material, if necessary, when forming the sealing resin layer 70.

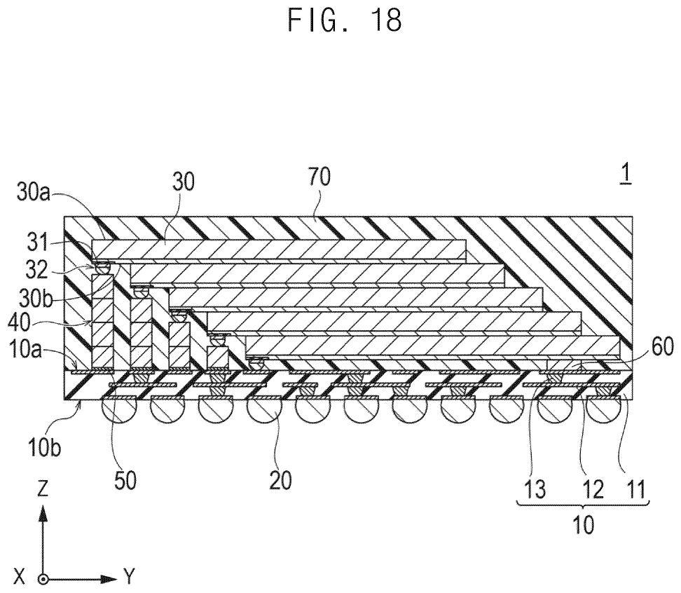

As illustrated in FIG. 18, in the terminal forming process (S9), the carrier substrate 100 may be removed and a connection terminal 20 may be formed on a B surface, i.e., a lower surface 10b, of the redistribution wiring layer 10. The semiconductor package 1 may be completed through the terminal forming process (S9).

Hereinafter, a description will be given of a modified example of a semiconductor package according one or more other embodiments. In one or more other embodiments described below, the same reference numerals are used to refer to the same elements as the above-described embodiments, and any further repetitive explanation concerning the above elements will be omitted. In addition, in each modified example, the configurations that are not specifically mentioned can be configured in the same manner as the above-described embodiments. In addition, each embodiment may be implemented by appropriately selecting a necessary configuration from among the configurations illustrated in each embodiment and combining it with other forms, within the scope that does not deviate from the gist of the present disclosure.

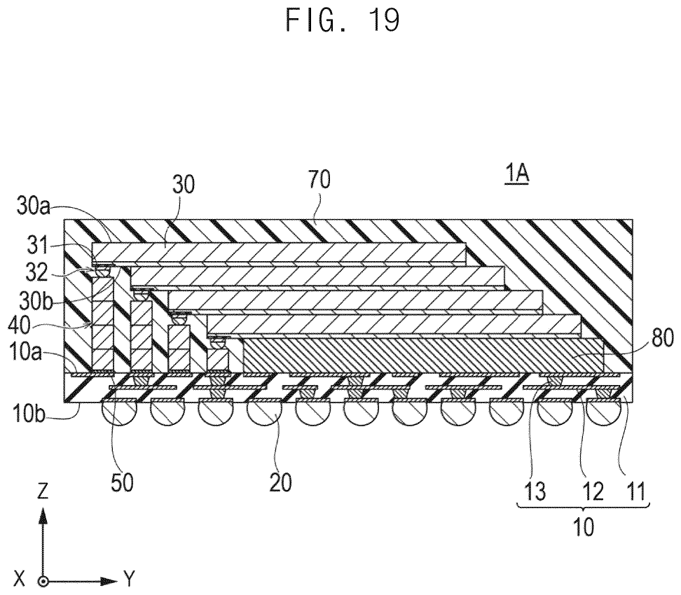

A semiconductor package 1A according to one or more other embodiments will described. FIG. 19 is a cross-sectional view illustrating a semiconductor package 1A according to modified example 1.

As illustrated in FIG. 19, a semiconductor package 1A of one or more other embodiments may differ from the aforementioned forms in a connection relationship between a semiconductor chip 30 and a redistribution wiring layer 10.

The semiconductor package 1A according to one or more other embodiments may include a chip mounting portion 80 that mounts the semiconductor chip 30 of the lowermost level, which is arranged closest to the redistribution wiring layer 10, as illustrated in FIG. 19. In the semiconductor package 1 described above, the semiconductor chip 30 of the lowermost level is directly connected to the redistribution wiring layer 10, and other semiconductor chips 30 are stacked on the semiconductor chip 30 of the lowermost level. In contrast, the semiconductor package 1A may have a configuration in which the lowermost semiconductor chip 30 is stacked on the chip mounting portion 80, and all the semiconductor chips 30 are connected to the redistribution wiring layer 10 by through electrodes 40.

The chip mounting portion 80 may mount the semiconductor chip 30 located at the lowermost level among the stacked semiconductor chips 30. The chip mounting portion 80 may be disposed on an A surface 10a of the redistribution wiring layer 10. The chip mounting portion 80 may electrically connect the redistribution wiring layer 10 and the semiconductor chip 30, or may not electrically connect the redistribution wiring layer 10 and the semiconductor chip 30.

The through electrode 40 of the semiconductor package 1A may be formed at a position on the A surface 10a of the redistribution wiring layer 10 to be individually connected to the semiconductor chip 30 stacked on the chip mounting portion 80.

The semiconductor package 1A of one or more other embodiments may be manufactured by performing the processes of the manufacturing method of the semiconductor package 1 described with reference to FIGS. 4 to 18. However, in the manufacturing method of the semiconductor package 1A of one or more other embodiments, the chip mounting portion forming process may be performed instead of the support member forming process (S3) in order to place the chip mounting portion 80 on the A surface 10a of the redistribution wiring layer 10.

In the chip mounting portion forming process, the chip mounting portion 80 may be placed on the A surface 10a of the redistribution wiring layer 10. In the method of manufacturing the semiconductor package 1A, after forming the chip mounting portion 80, the seed layer forming process (S4) may be performed to form a seed layer 50 on the A surface 10a of the redistribution wiring layer 10. In addition, in the connection process (S7), the semiconductor chip 30 located in the lowermost level may be mounted on the chip mounting portion 80 so that the connection portion 32 formed on the electrode 31 is exposed. Other semiconductor chips 30 may be stacked to be offset-aligned by a predetermined distance in a same direction (the second direction) (Y-axis direction) such that the connection portion 32 formed on the electrode 31 is exposed. Each of the semiconductor chips 30 stacked on the chip mounting portion 80 may be individually connected to the redistribution wiring layer 10 through the connection portion 32 and the through electrode 40, as illustrated in FIG. 19.

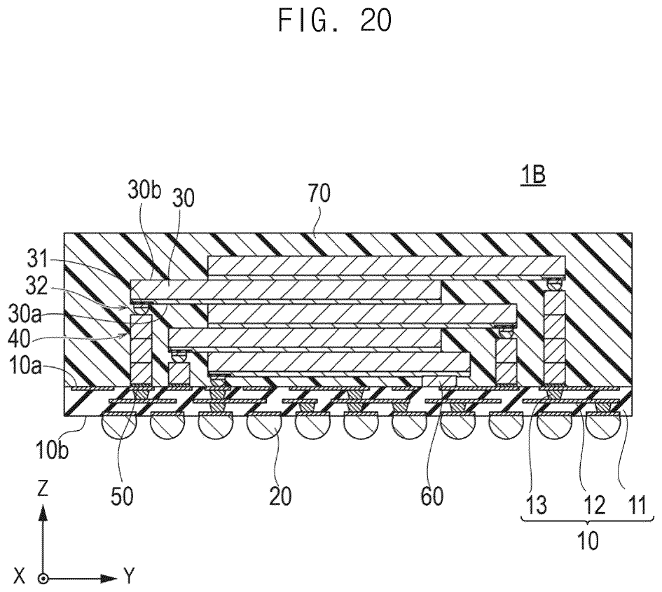

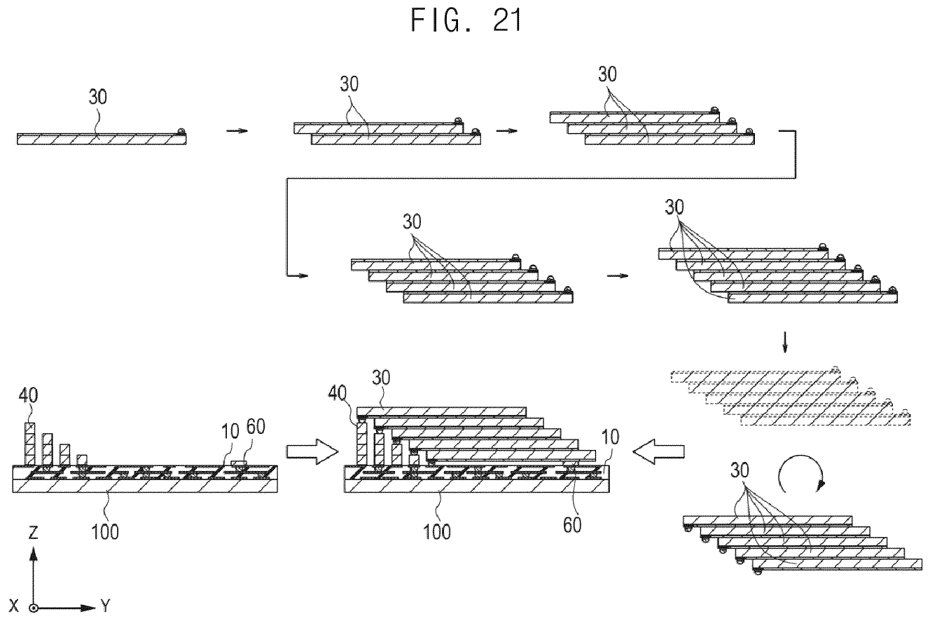

Hereinafter, a semiconductor package 1B according to one or more other embodiments will be described. FIG. 20 is a cross-sectional view illustrating a semiconductor package 1B according to one or more other embodiments.

As illustrated in FIG. 20, a semiconductor package 1B according to one or more other embodiments may have a different stacked structure of semiconductor chips 30 from the aforementioned form. In the semiconductor package 1B, a plurality of semiconductor chips 30 may have a stacked structure in which the semiconductor chips 30 are stacked in different directions in a second direction (Y-axis direction).

As illustrated in FIG. 20, the semiconductor package 1B according to one or more other embodiments may have a stacked structure in which electrodes 31 of the semiconductor chips 30 stacked on a semiconductor chip 30 arranged closest to the redistribution wiring layer 10 are exposed to be offset-aligned in different directions in the second direction (Y-axis direction). In FIG. 20, the semiconductor chip 30 located in the lowermost level may arranged in the central portion of the redistribution wiring layer 10 and may be directly connected to the redistribution wiring layer 10. The plurality of semiconductor chips 30 stacked on the semiconductor chip 30 of the lowermost level may have a stacked structure in which they are stacked to be offset-aligned in one of the left and right directions in the drawing so as to be connected to the corresponding through electrode 40. The semiconductor package 1B illustrated in FIG. 20 is a stacked structure in which the semiconductor chips 30 are alternately offset-aligned left and right in the second direction and the exposure positions are alternately positioned in the second direction (Y-axis direction). In addition, although the semiconductor package 1B of FIG. 20 has the semiconductor chips 30 alternately offset-aligned left and right, embodiments may not be limited thereto and may include a stacked structure in which they are offset-aligned in the same direction.

In the semiconductor package 1B, a through electrode 40 may be formed on the A surface 10a of the redistribution wiring layer 10 at a position that may be connected to a connection portion 32 of the semiconductor chip 30 to be connected. The semiconductor package 1B of the modified example 2 may be manufactured by performing the processes of the manufacturing method of the semiconductor package 1 described with reference to FIGS. 4 to 18. However, in the stacked structure of the semiconductor package 1B, the semiconductor chips 30 may be shifted and stacked in a different direction so that the electrodes 31 do not overlap in the second direction (Y-axis direction). Accordingly, in the manufacturing method of the semiconductor package 1B, the through electrode forming process (S5) may form the through electrode 40 in the first direction (Z-axis direction) toward the connection portion 32 of the semiconductor chip 30 to be connected. In addition, the connection process (S7) may arrange the stacking position of the semiconductor chip 30 in an offset-aligned manner in the second direction (Y-axis direction) to match the position of the through electrode 40.

The above semiconductor package 1, 1A, 1B has been described in such a way that, when shifting the semiconductor chip 30 in a stacked structure so that the electrodes 31 do not overlap, the first direction is the Z-axis direction, and the second direction (Y-axis direction) perpendicular to the first direction is the Y-axis direction. However, in the stacked structure, the semiconductor chips 30 may be stacked and shifted in the second direction (Y-axis direction) perpendicular to the first direction to the X-axis direction. For example, the semiconductor package 1, 1A, 1B may be stacked by appropriately shifting the semiconductor chip 30 along a plane (XY plane) orthogonal to the thickness direction (Z-axis direction) so that the electrodes 31 do not overlap. At that time, the through electrode 40 may be formed to extend from the A surface 10a of the redistribution wiring layer 10 in the first direction (Z-axis direction) toward the connection portion 32 of the semiconductor chip 30 to be connected.

In addition, the above semiconductor package 1, 1A, 1B is manufactured in the order in which the semiconductor chips 30 are sequentially stacked on the semiconductor chip 30 located at the lowermost level in the connection process (S7). However, the semiconductor chip 30 may be manufactured in the order in which the semiconductor chips 30 are sequentially stacked starting from the semiconductor chip 30 located at the highest level to form a chip stack, and after stacking, the top and bottom of the chip stack are reversed to connect the through electrode 40 to each semiconductor chip 30. For example, in the manufacturing method of the semiconductor package 1, 1A, 1B, the stacking order of the semiconductor chips 30 may not be particularly limited.

In addition, the chip mounting portion 80 added in the semiconductor package 1A may be adopted in the semiconductor package 1B. In this case, in the semiconductor package 1B, as in the semiconductor package 1A, all of the semiconductor chips 30 may be electrically connected to the redistribution wiring layer 10 through the through electrode 40.

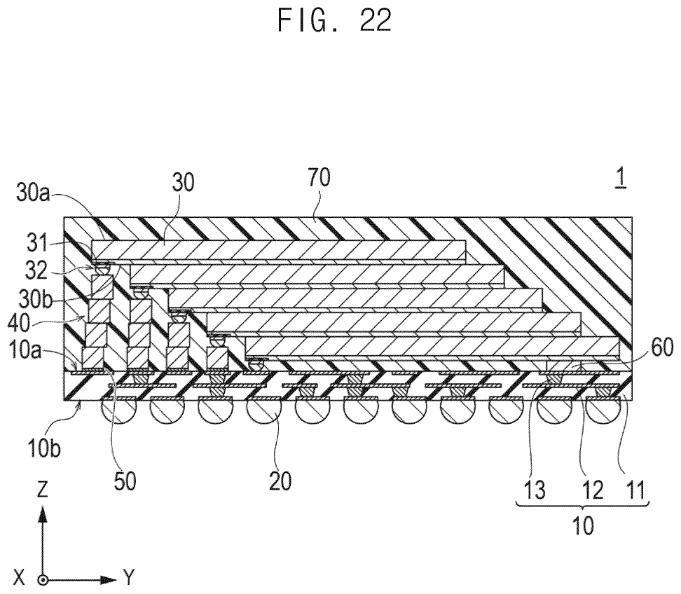

In addition, the above semiconductor package 1, 1A, 1B may be formed by stacking the axis center of the pillar-shaped portion 41 constituting the through electrode 40 so as to be misaligned with another pillar-shaped portion 41 to be stacked, as illustrated in FIG. 22, as another modified example.

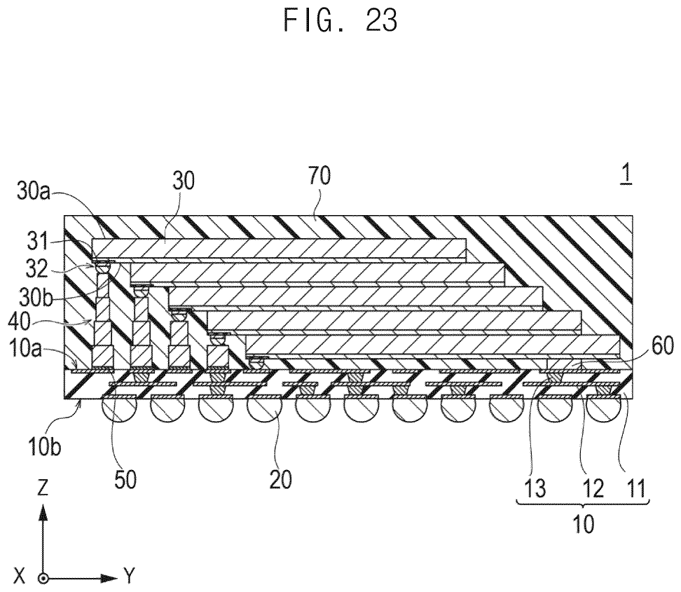

In addition, the above semiconductor package 1, 1A, 1B may be formed such that a width of the pillar-shaped portion 41 constituting the through electrode 40 is different from widths of other pillar-shaped portions 41 to be stacked, as illustrated in FIG. 23, as one or more other embodiments. In FIG. 23, the width of the pillar-shaped portion 41 arranged adjacent to the redistribution wiring layer 10 may be the widest, and the width of the pillar-shaped portion 41 connected to the electrode 31 may be the narrowest in the horizontal direction (X direction and/or Y direction). In FIG. 23, the width of the pillar-shaped portion 41 gradually decrease in the Z direction away from the redistribution wiring layer 10, but embodiments are not limited thereto, and the width of the pillar-shaped portion 41 may vary and decrease and/or increase in the Z direction.

When the semiconductor package 1, 1A, 1B adopts the form as illustrated in FIGS. 22 and 23, a stress relief effect may be obtained when the semiconductor chip 30 is shifted and stacked.

As described above, the semiconductor package according to one or more embodiments may include the semiconductor chip stack structure in which the plurality of semiconductor chips 30 having the first surface 30a and the second surface 30b opposite to the first surface 30a and having an electrode 31 formed on the second surface 30b, and the semiconductor chips 30 are stacked to be offset-aligned in the second direction perpendicular to the first direction so that the electrode 31 does not overlap with the first surface 30a of the adjacent semiconductor chip 30 in the first direction, which is a stacking direction of the semiconductor chips 30, the redistribution wiring layer 10 having the A surface 10a facing the semiconductor chip 30 and the B surface 10b opposite to the A surface 10a, having the connection terminal 20 formed on the B surface to be electrically connected to the mounting substrate 200, and electrically connected to the semiconductor chip 30, the sealing resin layer 70 sealing the semiconductor chips 30, and the plurality of through electrodes 40 configured with one or more conductive pillar-shaped portions 41 and electrically connecting the semiconductor chip 30 and the redistribution wiring layer 10 through the electrode 31, and each of the through electrodes 40 may extend in the first direction to penetrate the sealing resin layer 70 from the A surface 10a of the redistribution wiring layer 10 toward the electrode 31 of the semiconductor chip 30.

By this configuration, the semiconductor package 1 may be a device with relatively high capacity and high-performance and to which wide I/O is applied, while the manufacturing cost is reduced by simplifying the connection structure connecting the redistribution wiring layer 10 and the semiconductor chip 30. In addition, since the semiconductor package 1 has more materials available for forming the through electrode 40 than related wire bonding technology, the material may be arbitrarily selected according to the manufacturing cost, etc.

A method of manufacturing the semiconductor package according to example embodiments may include the preparation process (S1) of preparing the plurality of semiconductor chips 30 having the first surface 30a and the second surface 30b opposite the first surface 30a and having the electrode 31 on the second surface 30b and the connection portion 32 formed on the electrode 31 for electrically connecting to an external device, and the carrier substrate 100, the redistribution wiring layer forming process (S2) of forming the redistribution wiring layer 10 on the carrier substrate 100 and having the A surface 10a facing the semiconductor chip 30 and the B surface 10b opposite the A surface 10a and having the connection terminal 20 formed on the B surface 10b for electrically connecting to the mounting substrate 200, the support member forming process (S3) of forming the support member 60 for supporting the semiconductor chip 30 located closest to the redistribution wiring layer 10 on the A surface 10a of the redistribution wiring layer 10, the seed layer forming process (S4) of forming the seed layer 50 on the A surface 10a of the redistribution wiring layer 10, the through electrode forming process (S5) of repeatedly performing the processing of forming the resist layer 110 on the seed layer 50 and patterning the resist layer 110 by a photolithography method to form the through portion 42 penetrating in the thickness direction and the processing of forming the electrode portion 43 in each of the through portions 42 by a wet plating method to stack the pillar-shaped portions 41 according to the connection height with the semiconductor chip 30 to thereby form the through electrode 40, the removal process (S6) of removing the resist layer 110, the connection process (S7) of sequentially stacking and arranging the semiconductor chips 30 so that the connection portion 32 does not overlap with the first surface 30a in the second direction perpendicular to the first direction, which is the stacking direction, and directly connecting the through electrode 40 and the connection portion 32, and the sealing process (S8) of forming the sealing resin layer 70 that seals the plurality of semiconductors chips 30.

The semiconductor package manufactured by the above manufacturing method may have a package structure in which the through electrode 40 for electrically connecting the redistribution wiring layer 10 and the individual semiconductor chip 30 is formed so as to penetrate the sealing resin layer 70, and the connection portion 32 of the redistribution wiring layer 10 and the semiconductor chip 30 is directly connected by the through electrode 40. Accordingly, the semiconductor package 1 may be a device with high capacity and high performance and to which Wide I/O is applied, while the manufacturing cost is suppressed by simplifying the connection structure for connecting the redistribution wiring layer 10 and the semiconductor chip 30. In addition, since the semiconductor package 1 manufactured by the above manufacturing method has more materials available for forming the through electrode 40 than the conventional wire bonding technology, the material can be arbitrarily selected according to the manufacturing cost, etc.

According to one or more embodiments, there is provided a method of manufacturing a semiconductor package, the method including forming a plurality of semiconductor chips including a first surface and a second surface opposite to the first surface, providing an electrode on the second surface of each semiconductor chip of the plurality of semiconductor chips and a connection portion on the electrode, and a carrier substrate, forming a redistribution wiring layer on the carrier substrate, the redistribution wiring layer having a first surface facing the plurality of semiconductor chips and a second surface opposite to the first surface, the redistribution wiring layer including a connection terminal on the second surface and configured to electrically connect the redistribution wiring layer to a mounting substrate, forming a support portion configured to support a lowermost semiconductor chip, which is closest to the redistribution wiring layer, on the first surface of the redistribution wiring layer, forming a seed layer on the first surface of the redistribution wiring layer, forming a resist layer on the seed layer and patterning the resist layer to form a through portion penetrating the resist layer in a first direction, forming an electrode portion in the through portion, and forming a through electrode corresponding to the electrode portion, removing the resist layer, sequentially stacking the plurality of semiconductor chips to be offset in a second direction perpendicular to the first direction such that the connection portion is directly connected to the through electrode, and forming a sealing resin layer on the plurality of semiconductor chips.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package, comprising:
a semiconductor chip stack structure comprising:
a plurality of semiconductor chips respectively comprising a first surface and a second surface opposite to the first surface; and
an electrode on the second surface of each semiconductor chip of the plurality of semiconductor chips,
wherein the plurality of semiconductor chips are stacked in a first direction and offset in a second direction perpendicular to the first direction such that the electrode on each semiconductor chip of the plurality of semiconductor chips is exposed from the first surface of an adjacent semiconductor chip of the plurality of semiconductor chips;
a redistribution wiring layer comprising a first surface facing the plurality of semiconductor chips and a second surface opposite to the first surface, and comprising a connection terminal on the second surface of the redistribution wiring layer that is configured to be electrically connected to a mounting substrate and electrically connected to the plurality of semiconductor chips;
a sealing resin layer sealing the plurality of semiconductor chips; and
a plurality of through electrodes between the plurality of semiconductor chips and the redistribution wiring layer, each through electrode of the plurality of through electrodes comprising conductive pillar-shaped portions,
wherein each through electrode of the plurality of through electrodes extends in the first direction from the first surface of the redistribution wiring layer through the sealing resin layer toward the electrode of each semiconductor chip of the plurality of semiconductor chips.

2. The semiconductor package of claim 1, wherein each through electrode of the plurality of through electrodes comprises a boundary portion between the conductive pillar-shaped portions adjacent to each other in the first direction.

3. The semiconductor package of claim 1, further comprising:
a connection portion on the electrode of each semiconductor chip of the plurality of semiconductor chips, the connection portion being configured to be electrically connected to the redistribution wiring layer.

4. The semiconductor package of claim 3, wherein each through electrode of the plurality of through electrodes is directly connected to the connection portion.

5. The semiconductor package of claim 3, further comprising:
a support portion on the first surface of the redistribution wiring layer and in contact with the second surface of a lowermost semiconductor chip of the plurality of semiconductor chips,
wherein the connection portion is between the lowermost semiconductor chip and the redistribution wiring layer.

6. The semiconductor package of claim 3, wherein each of the conductive pillar-shaped portions is a pillar-shaped electrode comprising:
a through portion between the first surface of the redistribution wiring layer and the connection portion; and
an electrode portion in the through portion and configured to electrically connect the redistribution wiring layer and the connection portion.

7. The semiconductor package of claim 1, further comprising:
a seed layer on the first surface of the redistribution wiring layer.

8. The semiconductor package of claim 1, wherein each semiconductor chip of the plurality of semiconductor chips is stacked to be offset-aligned in a same direction in the second direction.

9. The semiconductor package of claim 1, wherein the plurality of semiconductor chips are stacked to be offset-aligned in different directions in the second direction.

10. The semiconductor package of claim 1, wherein the semiconductor package is a low-power double data rate (LPDDR) memory.

11. The semiconductor package of claim 1, further comprising:
a chip mounting portion on the first surface of the redistribution wiring layer,
wherein a lowermost semiconductor chip of the plurality of semiconductor chips is on the chip mounting portion.

12. A semiconductor package, comprising:
a redistribution wiring layer;
a plurality of semiconductor chips sequentially stacked on a first surface of the redistribution wiring layer in a first direction, a first surface of each semiconductor chip of the plurality of semiconductor chips facing the redistribution wiring layer, and the plurality of semiconductor chips being offset in a second direction perpendicular to the first direction to expose an electrode on the first surface of each semiconductor chip of the plurality of semiconductor chips;
a sealing resin layer sealing the plurality of semiconductor chips;
a connection portion on the electrode of each semiconductor chip of the plurality of semiconductor chips and configured to be electrically connected to the redistribution wiring layer; and
a plurality of through electrodes extending from the first surface of the redistribution wiring layer through the sealing resin layer to the connection portion,
wherein each through electrode of the plurality of through electrodes comprises conductive pillar-shaped portions.

13. The semiconductor package of claim 12, wherein each through electrode of the plurality of through electrodes comprises a boundary portion between the conductive pillar-shaped portions adjacent to each other in the first direction.

14. The semiconductor package of claim 13, wherein axis centers of the conductive pillar-shaped portions are offset from each other in the second direction or widths of the conductive pillar-shaped portions in the second direction are different from each other.

15. The semiconductor package of claim 12, wherein the through electrode is directly connected to the connection portion.

16. The semiconductor package of claim 12, further comprising:
a support portion on the first surface of the redistribution wiring layer and in contact with the first surface of a lowermost semiconductor chip of the plurality of semiconductor chips,
wherein the connection portion is between the lowermost semiconductor chip and the redistribution wiring layer.

17. The semiconductor package of claim 12, further comprising:
a seed layer on the first surface of the redistribution wiring layer.

18. The semiconductor package of claim 12, further comprising:
a chip mounting portion on the first surface of the redistribution wiring layer,
wherein a lowermost semiconductor chip of the plurality of semiconductor chips is on the chip mounting portion.

19. The semiconductor package of claim 12, wherein the plurality of semiconductor chips are stacked to be offset-aligned in a same direction or in different directions in the second direction.

20. A semiconductor package, comprising:
a redistribution wiring layer;
a plurality of semiconductor chips sequentially stacked on a first surface of the redistribution wiring layer in a first direction, a first surface of each semiconductor chip of the plurality of semiconductor chips facing the redistribution wiring layer, and being offset in a second direction perpendicular to the first direction such that each electrode on the first surface of each semiconductor chip of the plurality of semiconductor chips is exposed;
a sealing resin layer sealing the plurality of semiconductor chips; and
a plurality of through electrodes extending from the first surface of the redistribution wiring layer through the sealing resin layer toward the electrodes of the plurality of semiconductor chips,
wherein each through electrode of the plurality of through electrodes comprises conductive pillar-shaped portions, and
wherein axis centers of the conductive pillar-shaped portions are offset from each other in the second direction or widths of the conductive pillar-shaped portions are different from each other in the second direction.
